(19) United States
(12) Patent Application Publication
(10) Pub. No.: US 2018/0258519 A1
(43) Pub. Date: Sep. 13, 2018

(54) APPARATUS FOR VACUUM DEPOSITION ON A SUBSTRATE AND METHOD FOR MASKING THE SUBSTRATE DURING VACUUM DEPOSITION

(71) Applicant: Applied Materials, Inc., Santa Clara, CA (US)

(72) Inventor: John M. WHITE, Hayward, CA (US)

(21) Appl. No.: 15/760,719

(22) PCT Filed: Jan. 29, 2016
(86) PCT No.: PCT/US2016/015638

§ 371 Date: Mar. 16, 2018

Related U.S. Application Data
(60) Provisional application No. 62/252,900, filed on Nov. 9, 2015.
(60) Provisional application No. 62/246,401, filed on Oct. 26, 2015.
(60) Provisional application No. 62/246,095, filed on Oct. 25, 2015.

(51) Int. Cl. C23C 14/04; C23C 14/56; H01J 37/34; H01J 37/32

(52) U.S. Cl. CPC C23C 14/042; C23C 14/568; H01J 37/32779; H01J 37/3405; H01J 37/3411; C23C 14/564

(57) ABSTRACT

An apparatus for vacuum deposition on a substrate is provided. The apparatus includes a vacuum chamber having a deposition area, one or more deposition sources in the deposition area and configured for vacuum deposition on the substrate while the substrate is transported along a transport direction past the one or more deposition sources, and a masking arrangement in the deposition area and configured for masking at least one of a first edge portion and a second edge portion of the substrate while the substrate passes the masking arrangement and the one or more deposition sources. The first edge portion and the second edge portion are opposite edge portions of the substrate.

### FIELD

Embodiments of the present disclosure relate to an apparatus for vacuum deposition on a substrate and a method for masking a substrate during vacuum deposition. Embodiments of the present disclosure particularly relate to an apparatus configured for dynamic sputter deposition and a method using a stationary masking arrangement for masking a substrate while the substrate is transported past the stationary masking arrangement.

### BACKGROUND

Techniques for layer deposition on a substrate include, for example, sputter deposition, thermal evaporation, and chemical vapor deposition. A sputter deposition process can be used to deposit a material layer on the substrate, such as a layer of a conducting material or an insulating material. During the sputter deposition process, a target having a target material to be deposited on the substrate is bombarded with ions generated in a plasma region to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxynitride of the target material on the substrate.

Substrates such as glass substrates can be supported on carriers during processing of the substrate. The carrier drives the substrate through a processing system. A masking arrangement can be provided at the carrier to mask the substrate, wherein material is deposited on the exposed substrate portion. The masking arrangement can be provided by a frame of the carrier or can be provided as a separate entity mounted on the carrier.

During a deposition process, material is deposited on the masking arrangement. Accordingly, material will grow on the masking arrangement such that the masking configuration will change with the growth of the material. Further, the carrier having the masking arrangement has an increased weight that has to be transported through the processing system. Moreover, the masking arrangement has to be frequently cleaned and/or replaced in order to allow for proper masking.

In view of the above, new apparatuses for vacuum deposition on a substrate and methods for masking a substrate during vacuum deposition, that overcome at least some of the problems in the art are beneficial. The present disclosure particularly aims at providing apparatuses and methods that allow for an improved masking over an increased period of time.

### SUMMARY

In light of the above, an apparatus for vacuum deposition on a substrate and a method for masking the substrate during vacuum deposition are provided. Further aspects, benefits, and features of the present disclosure are apparent from the claims, the description, and the accompanying drawings.

According to an aspect of the present disclosure, an apparatus for vacuum deposition on a substrate is provided. The apparatus includes a vacuum chamber having a deposition area, one or more deposition sources in the deposition area and configured for vacuum deposition on the substrate while the substrate is transported along a transport direction past the one or more sputter deposition sources, and a masking arrangement in the deposition area and configured for masking at least one of a first edge portion and a second edge portion of the substrate while the substrate passes the masking arrangement and the one or more deposition sources, wherein the first edge portion and the second edge portion are opposite edge portions of the substrate.

According to another aspect of the present disclosure, a masking arrangement for use in an apparatus for vacuum deposition on a substrate is provided. The masking arrangement is configured to be mounted in a vacuum chamber of the apparatus stationary with respect to a transport direction of the substrate. The masking arrangement is configured for masking at least one of a first edge portion and a second edge portion of the substrate while the substrate passes the masking arrangement during a vacuum deposition process, wherein the first edge portion and the second edge portion are opposite edge portions of the substrate.

According to another aspect of the present disclosure, a masking arrangement for use in an apparatus for vacuum deposition on a substrate is provided. The masking arrangement is configured to be mounted in a vacuum chamber of the apparatus stationary with respect to a transport direction of the substrate. The masking arrangement is configured for masking at least one of a first edge portion and a second edge portion of the substrate while the substrate passes the masking arrangement during a vacuum deposition process, wherein the first edge portion and the second edge portion are opposite edge portions of the substrate. The masking arrangement includes a first masking device configured for masking the first edge portion of the substrate; and a second masking device configured for masking the second edge portion of the substrate, wherein the first masking device is configured to be movable in a first direction different than the transport direction, and wherein the second masking device is configured to be movable in a second direction different than the transport direction

According to a further aspect of the present disclosure, a method for masking a substrate during vacuum deposition is provided. The method includes a masking of at least one of a first edge portion and a second edge portion of the substrate using a masking arrangement while the substrate passes the masking arrangement and one or more deposition sources of the apparatus, wherein the first edge portion and the second edge portion are opposite edge portions of the substrate, and wherein the masking arrangement is stationary with respect to a transport direction of the substrate.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic top view of an apparatus for vacuum deposition on a substrate according to embodiments described herein;

FIG. 2 shows a schematic side view of the apparatus of FIG. 1;

FIG. 3 shows a schematic front view of the apparatus of FIGS. 1 and 2;

FIG. 4 shows a schematic view of a masking arrangement according to embodiments described herein;

FIG. 5 shows a schematic view of a masking arrangement according to further embodiments described herein; and

FIG. 6 shows a flow chart of a method for masking a substrate during vacuum deposition according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. The description shall include such modifications and variations.

During a vacuum deposition process, material is deposited on a masking arrangement. Material accumulates on the masking arrangement such that the masking configuration will change with the growth of the material. The device is beneficially frequently cleaned and/or replaced in order to allow for proper masking. Further, the masking arrangement can be provided at, or by, a carrier that holds the substrate as the carrier is driven through the apparatus. The carrier having the masking arrangement has an increased weight to be transported through the apparatus, making a handling of the carrier more complicated. Moreover, each carrier is equipped with a respective masking arrangement. Complexity and costs for the manufacture and/or maintenance of the carrier are increased.

The present disclosure provides a stationary masking arrangement provided in a deposition area of a vacuum chamber. The masking arrangement is provided within the vacuum chamber and is not moved along the transport direction of the substrate during a masking of the substrate. In particular, the masking arrangement is not provided at, or connected to, the carrier. Instead, the masking arrangement is provided as a separate entity remote from the carrier. Specifically, the masking arrangement does not contact the carrier and/or the substrate during the vacuum deposition process. The substrate, and in particular the carrier having the substrate positioned thereon, is transported past the stationary masking arrangement, e.g. in an in-line processing apparatus, during the vacuum deposition process such that material can be deposited on the exposed portions of the substrate. The term “masking” may include reducing and/or hindering a deposition of material on one or more regions of the substrate such as edge region(s).

The embodiments of the present disclosure can reduce the complexity of a carrier, minimizing costs for manufacture and/or maintenance of the carrier. A weight of the carrier can be reduced, facilitating a handling of the carrier. Further, one single masking arrangement is provided for masking a plurality of substrates that are transported past the masking arrangement during the vacuum deposition process, facilitating a cleaning process of the masking arrangement. In particular, only the stationary masking arrangement needs to be cleaned, instead of a plurality of masking arrangement, one provided at each of the carriers.

One more advantage of a stationary masking arrangement is the environmental conditions of the masks do not change. Since the masks do not move in and out of the vacuum system with each carrier and substrate, the masks do not experience temperature excursions and do not get exposed to ambient moisture while outside the vacuum system. This is beneficial because both of these conditions may cause changes in stress and adhesion of the deposited material on the mask, causing shedding of the deposits and particle-related defects on the substrate. Furthermore, the moisture which accumulates in and on the deposits can be deleterious to the films deposited on the substrates if that moisture is released once the carriers and masks reenter the vacuum system with fresh substrates to be deposited.

The apparatus can be configured for a dynamic vacuum deposition process. A dynamic vacuum deposition process can be understood as a vacuum deposition process in which the substrate is moved through the deposition area along a transport direction while the vacuum deposition process is conducted. In other words, the substrate is not stationary during the vacuum deposition process.

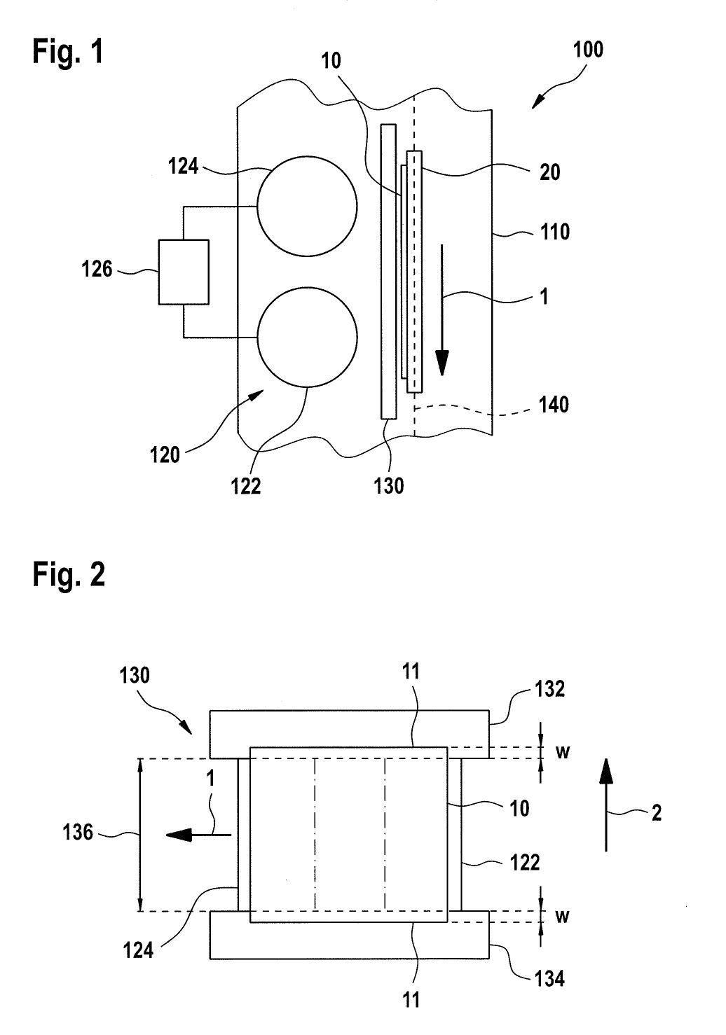

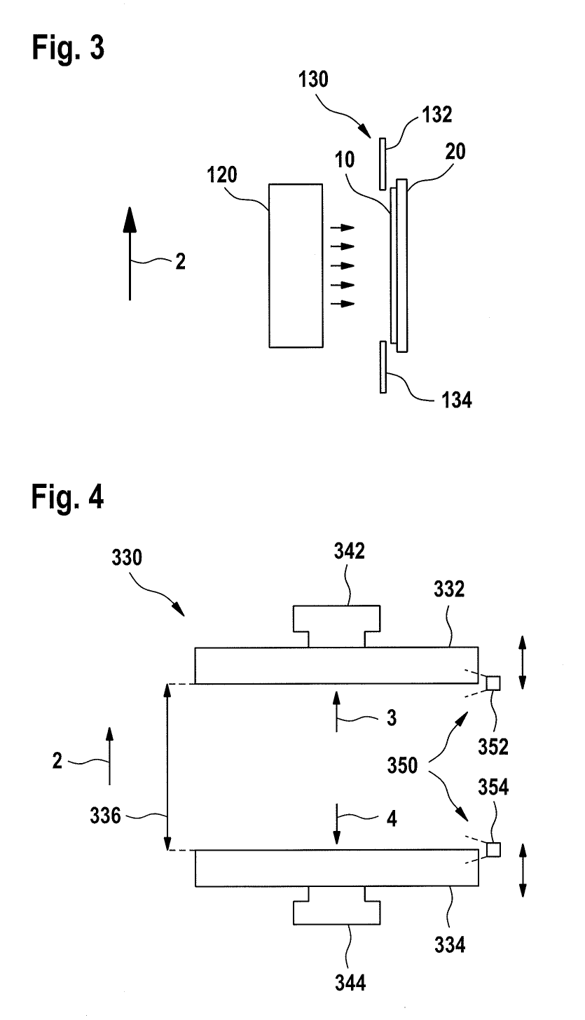

FIG. 1 shows a schematic top view of an apparatus 100 for vacuum deposition on a substrate 10 according to embodiments described herein. FIGS. 2 and 3 show further schematics views of the apparatus 100 of FIG. 1 from different perspective views.

The apparatus 100 includes a vacuum chamber 110 having a deposition area, one or more deposition sources 120, such as one or more sputter deposition sources, in the deposition area and configured for vacuum deposition on the substrate 10 while the substrate 10 is transported along a transport direction 1 past the one or more sputter deposition sources 120. The apparatus 100 further includes a masking arrangement 130 in the deposition area and configured for masking at least one of a first edge portion and a second edge portion of the substrate 10 while the substrate 10 passes the masking arrangement 130 and the one or more deposition sources 120. The masking arrangement 130 is provided between the one or more deposition sources 120 and the substrate 10 in order to shield portions (e.g., the first edge portion and/or the second edge portion) of the substrate 10 from being coated. In some implementations, the masking arrangement 130 can be referred to as “edge exclusion mask”. The masking arrangement 130 can mask one edge portion, such as the first edge portion or the second edge portion, or can mask two edge portions, such as the first edge portion and the second edge portion.

The term “edge portion” may refer to a thin region of the substrate 10 at or near the edge of the substrate 10. An edge portion may include a respective edge 11 of the substrate 10, as illustrated in FIG. 2. The terminology of an “edge” of the substrate 10 may refer to a line-like limiting portion of the substrate 10 where the material of the substrate 10 terminates. The edge portion of the substrate 10 according to the embodiments described herein may refer to the region or area of the substrate 10 being masked by the masking arrangement 130 in the vacuum deposition process. According to some embodiments, which can be combined with other embodiments described herein, the edge portion of the substrate 10 may have an area of about 5% or less of the area of the substrate 10, particularly about 2% or less, and more particularly between about 1% to about 2% of the area of the substrate 10.

As shown in FIG. 2, the edge portion(s), such as the first edge portion and/or the second edge portion, may have a width W. According to some embodiments, which can be combined with other embodiments described herein, the width of the edge portion may be 15 mm or less, particularly 10 mm or less, and more particularly 5 mm or less. The width W of the edge portion may be substantially the same for all edge portions, such as the first edge portion and the second edge portion. In other embodiments, the widths of the edge portions may be different for at least some of the edge portions. As an example, the width of the first edge portion and the width of the second edge portion can be different.

The substrate 10 can be positioned on a carrier 20. The carrier 20 can be configured for transportation along a transportation path 140 or transportation track extending in the transport direction 1. The carrier 20 is configured to support the substrate 10, for example, during a vacuum deposition process or layer deposition process, such as a sputtering process or a dynamic sputtering process. The carrier 20 can include a plate or a frame configured for supporting the substrate 10, for example, using a support surface provided by the plate or frame. Optionally, the carrier 20 can include one or more holding devices (not shown) configured for holding the substrate 10 at the plate or frame. The one or more holding devices can include at least one of mechanical, electrostatic, electrodynamic (van der Waals), electromagnetic devices. As an example, the one or more holding devices can be mechanical and/or magnetic clamps.

In some implementations, the carrier 20 includes, or is, an electrostatic chuck (E-chuck). The E-chuck can have a supporting surface for supporting the substrate thereon. In one embodiment, the E-chuck includes a dielectric body having electrodes embedded therein. The dielectric body can be fabricated from a dielectric material, preferably a high thermal conductivity dielectric material such as pyrolytic boron nitride, aluminum nitride, silicon nitride, alumina or an equivalent material. The electrodes may be coupled to a power source, which provides power to the electrodes to control a chucking force. The chucking force is an electrostatic force acting on the substrate to fix the substrate 10 on the supporting surface.

In some implementations, the carrier 20 includes, or is, an electrodynamic chuck or Gecko chuck (G-chuck). The G-chuck can have a supporting surface for supporting the substrate thereon. The chucking force is an electrodynamic force acting on the substrate to fix the substrate 10 on the supporting surface.

According to some embodiments, which can be combined with other embodiments described herein, the carrier 20 is configured for supporting the substrate 10 in a substantially vertical orientation, in particular during the vacuum deposition process. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Further, fewer particles reach the substrate surface when the substrate is tilted forward. Yet, the substrate orientation, e.g., during the vacuum deposition process, is considered substantially vertical, which is considered different from the horizontal substrate orientation, which may be considered as horizontal ±20° or below.

The masking arrangement 130 is stationary with respect to the transport direction 1 of the substrate 10, in particular while the substrate 10 passes the masking arrangement 130 and the one or more deposition sources 120. The term “stationary” is to be understood in the sense that the masking arrangement 130 is not moved along the transport direction 1. In particular, the masking arrangement 130 can be stationary relative to the vacuum chamber 110 in the transport direction 1. However, in some implementations the masking arrangement 130 or elements of the masking arrangement 130 can be moved in directions perpendicular to the transport direction 1. Still, the masking arrangement 130 is considered to be stationary with respect to the transport direction 1.

The first edge portion and the second edge portion can be opposite edge portions of the substrate 10. The first edge portion and the second edge portion can extend substantially parallel to each other. A surface area of the substrate 10 on which material is to be deposited during the vacuum deposition process can be provided between the first edge portion and the second edge portion. According to some embodiments, which can be combined with other embodiments described herein, the first edge portion is an upper edge portion of the substrate 10 and the second edge portion is a lower edge portion of the substrate 10, for example, when the substrate 10 is in the substantially vertical orientation. For instance, the first edge portion and the second edge portion can be substantially horizontal edge portions.

The masking arrangement 130 may be useful, for instance, in order to better define the area to be coated. In some applications, only parts of the substrate 10 are to be coated and the parts not to be coated are covered by the masking arrangement 130. According to some embodiments, the masking arrangement 130 can be configured for edge exclusion. Edge exclusion can be used to exclude the edge of the substrate 10 from being coated. With the exclusion of the edge one can provide coating free substrate edges and to prevent a coating of the backside of the substrate 10. For example, in some applications such as liquid crystal displays, a non-coated substrate edge may be beneficial.

The embodiments described herein can be utilized for evaporation on large area substrates, e.g., for display manufacturing. Specifically, the substrates or carriers, for which the structures and methods according to embodiments described herein are provided, are large area substrates. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein shall particularly embrace inflexible substrates, e.g., glass plates and metal plates. However, the present disclosure is not limited thereto and the term “substrate” can also embrace flexible substrates such as a web or a foil. According to some embodiments, the substrate 10 can be made of any material suitable for material deposition. For instance, the substrate 10 can be made of a material selected from the group consisting of glass (for instance soda-lime glass, borosilicate glass, and the like), metal, polymer, ceramic, compound materials, carbon fiber materials, mica or any other material or combination of materials which can be coated by a deposition process.

According to some embodiments, which can be combined with other embodiments described herein, the masking arrangement 130 includes a first masking device 132 configured for masking the first edge portion of the substrate 10 and a second masking device 134 configured for masking the second edge portion of the substrate 10. As an example, the first masking device 132 can be configured for masking the upper edge portion of the substrate 10 and the second masking device 134 can be configured for masking the lower edge portion of the substrate 10. The first masking device 132 can be an upper masking device, and the second masking device 134 can be a lower masking device. The masking arrangement 130, and particularly the first masking device 132 and the second masking device 134 do not contact the substrate 10 during the vacuum deposition process. In other words, the masking arrangement 130 is separated from the substrate 10.

The first masking device 132 and the second masking device 134 can be spaced apart from each other by a distance 136. The space between the first masking device 132 and the second masking device 134 provided by the distance 136 can define a coating area of the substrate 10. The distance 136 can be defined between opposite edges of the first masking device 132 and the second masking device 134. The edges of the first masking device 132 and the second masking device 134 can extend substantially parallel to each other. In some implementations, the first masking device 132 and the second masking device 134 can be horizontal masking devices. When deposition material accumulates on the edges of the first masking device 132 and/or the second masking device 134, the distance 136 can be defined as a distance between opposite surfaces of the material accumulated on the edges of the first masking device 132 and the second masking device 134. In particular, the distance 136 can be defined based on the free space between the first masking device 132 and the second masking device 134, e.g., through which deposition material can reach the substrate 10.

According to some embodiments, which can be combined with other embodiments described herein, the masking arrangement 130 is configured to be moveable in a direction different from the transport direction 1, for example, in a direction substantially perpendicular to the transport direction 1. The term “substantially perpendicular” relates to a substantially perpendicular movement of the masking arrangement 130 with respect to the transport direction 1, wherein a deviation of a few degrees, e.g. up to 10° or even up to 15°, from an exact perpendicular movement is still considered as a “substantially perpendicular movement”.

During the vacuum deposition process, material is deposited on the masking arrangement 130. In particular, material can accumulate on edges of the masking arrangement 130, such as the opposing edges of the first masking device 132 and the second masking device 134. The material accumulation changes a size of the coating area, e.g., by changing the distance 136 due to the growth of the material on the edges of the first masking device 132 and the second masking device 134. The masking arrangement 130 can be configured to compensate for deposition material accumulation on the masking arrangement 130. In particular, the masking arrangement 130 or one or more elements of the masking arrangement 130 can be moved in the direction perpendicular to the transport direction 1 in order to compensate for the material accumulation on one or more edges of the masking arrangement 130. The masking arrangement 130 can be cleaned and/or replaced less frequently. An improved masking over an increased period of time can be provided.

In some implementations, the masking arrangement 130 is configured to be movable in a vertical direction 2. In particular, the direction perpendicular to the transport direction 1 can be the vertical direction 2. A substrate motion, e.g., in the transport direction 1, can be substantially horizontal. The term “vertical direction” or “vertical orientation” is understood to distinguish over “horizontal direction” or “horizontal orientation”. That is, the “vertical direction” or “vertical orientation” relates to a substantially vertical direction of a movement and/or the substantially vertical orientation e.g. of the carrier and the substrate 10, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

According to some embodiments, the first masking device 132 is configured to be movable in a first direction perpendicular to the transport direction 1, and the second masking device 134 is configured to be movable in a second direction opposite the first direction. The first direction and the second direction can be vertical directions. As an example, the first masking device 132 and the second masking device 134 can be movable in order to reduce or increase the distance 136. In particular, the distance 136 can be increased in order to compensate for material accumulation on the first masking device 132 and/or the second masking device 134.

In some embodiments, the first masking device 132 and the second masking device 134 can be configured to be movable in the same direction, for example, the first direction and/or the second direction. The space between the first masking device 132 and the second masking device 134 that is defined by the distance 136 can be displaced, for example, in order to align the masking arrangement 130 with respect to the carrier 20 and/or the substrate 10. In some implementations, the distance 136 can be kept constant or can be changed when the first masking device 132 and the second masking device 134 are moved in the same direction.

According to some embodiments, which can be combined with other embodiments described herein, the masking arrangement 130 can be configured to be movable at least one of (i) while the substrate 10 passes the masking arrangement 130, (ii) before the substrate 10 passes the masking arrangement 130, and (iii) after the substrate 10 has passed the masking arrangement 130. As an example, the masking arrangement 130 can be moved continuously or stepwise.

In some implementations, the distance 136 between the first masking device 132 and the second masking device 134 can be adjusted in order to compensate for material accumulation on one or more edges of the masking arrangement 130. As an example, the first masking device 132 and/or the second masking device 134 can be moved in opposite directions to increase the distance 136.

According to some embodiments, the adjustment can be conducted before the substrate 10 passes the masking arrangement 130 in order to provide for an improved masking of the substrate 10 to be processed. Additionally or alternatively, an adjustment can be conducted after the substrate 10 has passed the masking arrangement 130, for example, based on process parameters such as at least one of a sputter power and a deposition rate used in the deposition process of the substrate 10. As an example, an amount of material that accumulates on the masking arrangement 130 may depend on the sputter power and/or the deposition rate. The adjustment can be conducted based on the amount that has accumulated on the masking arrangement 130. An improved masking for a subsequent substrate can be provided. Further additionally or alternatively, an adjustment can be conducted while the substrate 10 passes the masking arrangement 130 in order to compensate for an accumulation of material during the deposition process, for example, in real-time. The distance 136 or the size of the coating area can be kept substantially constant, improving masking conditions.

According to some embodiments, one single vacuum chamber, such as the vacuum chamber 110, for deposition of layers therein can be provided. A configuration with one single vacuum chamber can be beneficial in an in-line processing apparatus, for example, for dynamic deposition. The one single vacuum chamber, optionally with different areas, does not include devices for vacuum tight sealing of one area of the vacuum chamber with respect to another area of the vacuum chamber. In other implementations, further chambers can be provided adjacent to the vacuum chamber 110. The vacuum chamber 110 can be separated from adjacent chambers by a valve, which may have a valve housing and a valve unit.

In some embodiments, an atmosphere in the vacuum chamber 110 can be individually controlled by generating a technical vacuum, for example with vacuum pumps connected to the vacuum chamber 110, and/or by inserting process gases in the deposition area in the vacuum chamber 110. According to some embodiments, process gases can include inert gases such as argon and/or reactive gases such as oxygen, nitrogen, hydrogen and ammonia (NH3), Ozone (O3), activated gases or the like.

The one or more deposition sources 120 can include a first deposition source 122 and a second deposition source 124. The one or more deposition sources 120 can for example be rotatable cathodes having targets of the material to be deposited on the substrate 10. The cathodes can be rotatable cathodes with a magnetron therein. Magnetron sputtering can be conducted for deposition of the layers. Exemplarily, the first deposition source 122 and the second deposition source 124 are connected to an AC power supply 126 such that the first deposition source 122 and the second deposition source 124 can be biased in an alternating manner. However, the present disclosure is not limited thereto and the one or more deposition sources 120 can be configured for DC sputtering or a combination of AC and DC sputtering.

As used herein, “magnetron sputtering” refers to sputtering performed using a magnet assembly, that is, a unit capable of generating a magnetic field. Such a magnet assembly can consist of a permanent magnet. This permanent magnet can be arranged within a rotatable target or coupled to a planar target in a manner such that the free electrons are trapped within the generated magnetic field originating below the rotatable target surface. Such a magnet assembly may also be arranged coupled to a planar cathode.

According to some embodiments, the apparatus 100 is configured for a dynamic vacuum deposition process. As an example, the apparatus 100 is configured for dynamic sputter deposition on the substrate 10. A dynamic vacuum deposition process can be understood as a vacuum deposition process in which the substrate 10 is moved through the deposition area along the transport direction 1 while the vacuum deposition process is conducted. In other words, the substrate 10 is not stationary during the vacuum deposition process.

In some implementations, the apparatus 100 for dynamic processing according to embodiments of the present disclosure is an in-line processing apparatus, i.e. an apparatus for dynamic deposition, particularly for dynamic vertical deposition, such as sputtering. An in-line processing apparatus or a dynamic deposition apparatus according to embodiments described herein provides for a uniform processing of the substrate 10, for example, a large area substrate such as a rectangular glass plate. The processing tools such as the one or more deposition sources 120 extend mainly in one direction (e.g., the vertical direction 2) and the substrate 10 is moved in a second, different direction (e.g., the transport direction 1 which can be the horizontal direction).

Apparatuses or systems for dynamic vacuum deposition, such as in-line processing apparatuses or systems, have the advantage that processing uniformity, for example, layer uniformity, in one direction is only limited by the ability to move the substrate 10 at a constant speed and to keep the one or more deposition sources 120 stable. The deposition process of an in-line processing apparatus or a dynamic deposition apparatus is determined by the movement of the substrate 10 past the one or more deposition sources 120. For an in-line processing apparatus, the deposition area or processing area can be an essentially linear area for processing, for example, a large area rectangular substrate. The deposition area can be an area into which deposition material is ejected from the one or more sputter deposition sources 120 to be deposited on the substrate 10. In contrast thereto, for a stationary processing apparatus, the deposition area or processing area would basically correspond to the area of the substrate 10.

In some implementations, a further difference of an in-line processing apparatus, for example, for dynamic deposition, as compared to a stationary processing apparatus can be formulated by the fact that the apparatus 100 can have one single vacuum chamber, optionally with different areas, wherein the vacuum chamber does not include devices for vacuum tight sealing of one area of the vacuum chamber with respect to another area of the vacuum chamber. Contrary thereto, a stationary processing system may have the first vacuum chamber and a second vacuum chamber which can be vacuum tight sealed with respect to each other using, for example, valves.

According to some embodiments, the apparatus 100 includes a magnetic levitation system for holding the carrier 20 in a suspended state. Optionally, the apparatus 100 can use a magnetic drive system configured for moving or conveying the carrier 20 in the transport direction 1. The magnetic drive system can be included in the magnetic levitation system or can be provided as a separate entity.

FIG. 4 shows a schematic view of a masking arrangement 330 according to embodiments described herein.

According to some embodiments, which can be combined with other embodiments described herein, a masking arrangement for use in an apparatus for vacuum deposition on a substrate is provided. The masking arrangement is configured to be mounted in a vacuum chamber of the apparatus stationary with respect to a transport direction of the substrate. The masking arrangement is configured for masking at least one of a first edge portion and a second edge portion of the substrate while the substrate passes the masking arrangement during a vacuum deposition process. The first edge portion and the second edge portion are opposite edge portions of the substrate, such as an upper edge portion and a lower edge portion of the substrate. The substrate can be held substantially flat and the plane of the substrate can be oriented vertically.

In some implementations, the masking arrangement 330 includes one or more actuators configured to move the masking arrangement 330, for example, continuously or stepwise. The masking arrangement 330 includes the first masking device 332 configured for masking the first edge portion of the substrate and the second masking device 334 configured for masking the second edge portion of the substrate. The first masking device 332 and the second masking device 334 are spaced apart from each other by the distance 336. The distance 336 can be defined along the vertical direction 2. The one or more actuators include a first actuator 342 connected to the first masking device 332 and the second actuator 344 connected to the second masking device 334. The one or more actuators can be selected from the group consisting of stepper motors, linear motors, electric motors, pneumatic motors, and any combination thereof.

The masking arrangement 330 can be configured to mask one edge portion of the substrate, such as the first edge portion or the second edge portion. The masking arrangement 330 can be configured to mask two edge portions of the substrate, such as the first edge portion and the second edge portion. The masking arrangement 330 can be configured to mask the one or more edge portions independently from a size of the substrate.

The masking arrangement 330 is configured to be moveable in a direction different from the transport direction 1, for example, in a direction substantially perpendicular to the transport direction 1. As an example, the masking arrangement 330 can be movable in the vertical direction 2. The first masking device 332 can be movable in the first direction 3 and the second masking device 334 can be movable in the second direction 4. The first direction 3 and the second direction 4 can be opposite directions such that the distance 336 between the first masking device 332 and the second masking device 334 can be increased or decreased.

During the vacuum deposition process, material is deposited on the masking arrangement 330. Material accumulates for example on edges, such as the edge of the first masking device 332 and the edge of the second masking device 334, such that the distance 336 will decrease due to the growth of the material on the edges. The masking arrangement 330 is configured to compensate for deposition material accumulation on the masking arrangement 130. As an example, the first masking device 332 can be moved upwards (in the first direction 3) and/or the second masking device 334 can be moved downwards (in the second direction 4) in order to compensate for material accumulation on one or more edges of the masking arrangement 330.

According to some embodiments, and as described with respect to FIGS. 1 to 3, the one or more actuators can be configured to move the masking arrangement 330 at least one of (i) while the substrate passes the masking arrangement 330, (ii) before the substrate passes the masking arrangement 330, and (iii) after the substrate has passed the masking arrangement 330.

According to some embodiments, which can be combined with other embodiments described herein, the apparatus for vacuum deposition, and in particular the masking arrangement, includes one or more detecting devices 350 configured for detecting a deposition material accumulation on at least a portion of the masking arrangement 330. As an example, the one or more detecting devices 350 include a first detecting device 352 provided at the first masking device 332 for detecting a deposition material accumulation on the first masking device 332. The one or more detecting devices 350 include a second detecting device 354 provided at the second masking device 334 for detecting a deposition material accumulation on the second masking device 334. The one or more detecting devices 350 can be optical devices, such as cameras.

A control of the movement of the masking arrangement 330 in the direction perpendicular to the transport direction, for example, the vertical direction 2, can be conducted based on information provided by the one or more detecting devices 350. As an example, the apparatus for vacuum deposition can include a control device (not shown) configured to receive and process information from the one or more detecting devices 350. The control device can be configured to control the one or more actuators based on information received from the one or more detecting devices 350. As an example, the control device can be configured to control the one or more actuators such that the distance 336 or the coating area on the substrate provided between the first masking device 332 and the second masking device 334 is kept substantially constant.

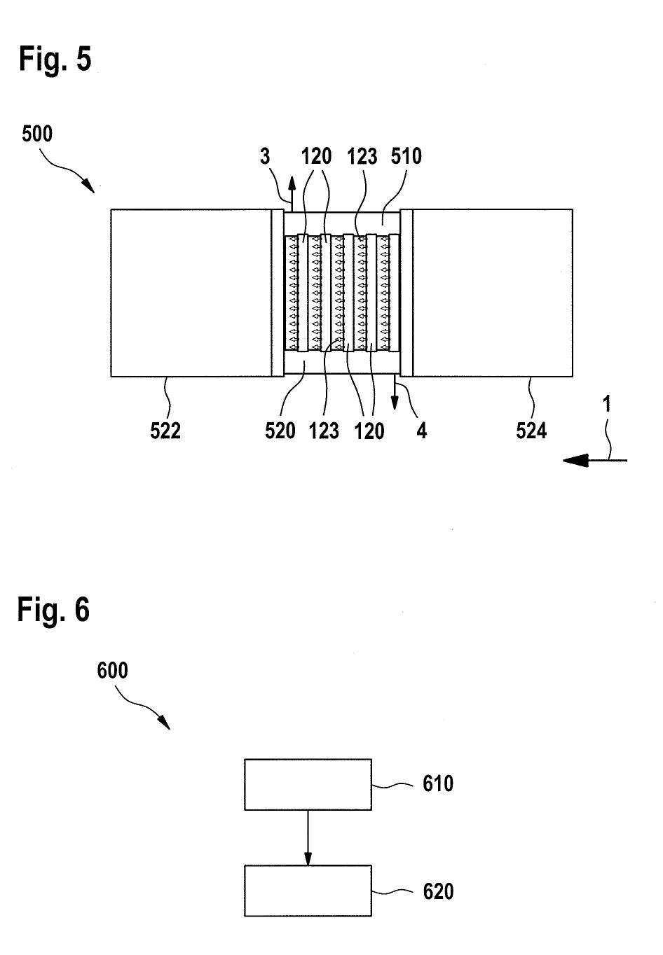

FIG. 5 shows a schematic view of a masking arrangement 500 according to further embodiments described herein. FIG. 5 particularly shows an edge exclusion for dynamic vertical deposition in an in-line deposition system.

According to some embodiments, which can combined with other embodiments described herein, the masking arrangement 500 is configured for masking at least one lateral edge portion of the substrate while the substrate passes the masking arrangement 500 during the vacuum deposition process. As an example, the at least one lateral edge portion can be a leading edge portion and/or a tailing edge portion of the substrate with respect to the transport direction. In some implementations, the at least one lateral edge portion can be a vertical edge of the substrate when the substrate is in the vertical orientation.

According to some embodiments, which can be combined with other embodiments described herein, the masking arrangement 500 can include at least one of a first lateral masking device 522 and a second lateral masking device 524 configured for masking the at least one lateral edge portion of the substrate. The first masking device 510 configured for masking the first edge portion of the substrate and the second masking device 520 configured for masking the second edge portion of the substrate can be provided between the first lateral masking device 522 and the second lateral masking device 524. As an example, the first lateral masking device 522 and the second lateral masking device 524 can be vertical masking devices. The first masking device 510 and the second masking device 520 can be horizontal masking devices.

According to some embodiments, the first masking device 510, the second masking device 520, the first lateral masking device 522 and the second lateral masking device 524 can define an aperture opening. Deposition material from the one or more sputter deposition sources 120 can pass through the aperture opening and can be deposited on the portion of the substrate 10 exposed by the aperture opening.

As shown in FIG. 5, the deposition area and the one or more deposition sources 120 can be provided between the first lateral masking device 522 and the second lateral masking device 524. The substrate is moved past the material emission, which is indicated by arrows 123.

According to some embodiments, the masking arrangement 500 can include one or more edge exclusion shields, such as the first masking device 510, the second masking device 520, the first lateral masking device 522 and the second lateral masking device 524. The first masking device 510 can be an upper edge exclusion and the second masking device 520 can be a lower edge exclusion. The upper edge of the substrate and the lower edge of the substrate can be masked in order to avoid deposition of material on the upper edge and the lower edge of the substrate.

The edge can have a width of about 0.1 mm to 10 mm. Upon operation of the in-line deposition system, the edge exclusions, particularly the first masking device 510 and the second masking device 520, will be deposited with material from the one or more deposition sources 120. Material will grow on the edges of the edge exclusion such that the geometrical position of the masking will change due to a growth of the material on the edges of the masking arrangement 500. According to some embodiments, which can be combined with other embodiments described herein, the first masking device 510 and the second masking device 520 can be moved up and down, respectively, as indicated by arrows “3” and “4”. This allows for an adjustment of the edge masking independent of the growth of material on the edge exclusion.

As shown in FIG. 5, an edge exclusion is provided within the vacuum chamber. The edge exclusion remains in the vacuum chamber and is not moved along the transport direction 1 of the substrate during the masking of the substrate. In particular, the edge exclusion is stationary with respect to the vacuum chamber. Complexity and a weight of the carrier on which the substrate is positioned can be reduced.

FIG. 6 shows a flowchart of a method 600 for masking a substrate during vacuum deposition. The method 600 can be implemented using the apparatus for vacuum deposition according to the embodiments described herein.

The method 600 includes in block 610 a masking of at least one of a first edge portion and a second edge portion of the substrate using a masking arrangement while the substrate passes the masking arrangement and one or more deposition sources of the apparatus, wherein the first edge portion and the second edge portion are opposite edge portions of the substrate, and wherein the masking arrangement is stationary with respect to a transport direction of the substrate. The method 600 can further include a deposition of material on the substrate while the substrate passes the one or more deposition sources and the masking arrangement. The masking arrangement can be configured according to the embodiments described therein.

In some implementations, the method 600 includes in block 620 a moving of the masking arrangement or of one or more elements of the masking arrangement, such as the first masking device and/or the second masking device, in a direction perpendicular to the transport direction of the substrate in order to compensate for deposition material accumulation on the masking arrangement. According to some embodiments, the compensation can be achieved by adjusting the distance between the first masking device and the second masking device.

For example, the adjustment can be conducted before the substrate passes the masking arrangement in order to provide for an improved masking of the substrate to be processed. Additionally or alternatively, an adjustment can be conducted after the substrate has passed the masking arrangement, for example, based on process parameters such as at least one of a sputter power and a deposition rate used in the deposition process for layer deposition on the substrate. An improved masking for a subsequent substrate can be provided. Further additionally or alternatively, an adjustment can be conducted while the substrate passes the masking arrangement in order to compensate for an accumulation of material during the deposition process in real-time.

According to embodiments described herein, the method for masking the substrate during vacuum deposition can be conducted using computer programs, software, computer software products and the interrelated controllers, which can have a CPU, a memory, a user interface, and input and output devices being in communication with the corresponding components of the apparatus for vacuum deposition on a substrate according to the embodiments described herein.

The present disclosure provides a stationary masking arrangement in a deposition area of a vacuum chamber. The masking arrangement is provided within the vacuum chamber and is not moved along the transport direction of the substrate during masking of the substrate. In particular, the masking arrangement is not provided at, or connected to, the carrier. Instead, the masking arrangement is provided as a separate entity remote from the carrier and does not contact the substrate or the carrier. The substrate, and in particular the carrier having the substrate positioned thereon, is transported past the stationary masking arrangement during a vacuum deposition process such that material can be deposited on the exposed portions of the substrate.

The embodiments of the present disclosure provide at least some of the following advantages. The apparatuses and methods according to embodiments described herein can reduce a complexity of a carrier, minimizing costs for manufacture and/or maintenance of the carrier. A weight of the carrier can be reduced, facilitating a handling of the carrier. Further, one masking arrangement is provided for masking a plurality of substrates that are transported past the masking arrangement during a vacuum deposition process, facilitating a cleaning process of the masking arrangement. In particular, only the stationary masking arrangement needs to be cleaned, instead of a plurality of masking arrangements provided at each of the carriers. Further, particle defects which may be attributed to thermal cycling and repeated ambient moisture exposure of the accumulated mask deposits can be avoided due to the fact the masking arrangement remains inside the vacuum chamber.

While the foregoing is directed to embodiments of the disclosure, other and further embodiments of the disclosure may be devised without departing from the basic scope thereof, and the scope thereof is determined by the claims that follow.

1. An apparatus for vacuum deposition on a substrate, comprising:
a vacuum chamber having a deposition area;
one or more deposition sources in the deposition area and configured for vacuum deposition on the substrate while the substrate is transported along a transport direction past the one or more deposition sources; and
a masking arrangement in the deposition area and configured for masking at least one of a first edge portion and a second edge portion of the substrate while the substrate passes the masking arrangement and the one or more deposition sources, wherein the first edge portion and the second edge portion are opposite edge portions of the substrate.

2. The apparatus of claim 1, wherein the first edge portion is an upper edge portion of the substrate and the second edge portion is a lower edge portion of the substrate.

3. The apparatus of claim 1, wherein the masking arrangement is configured to be moveable in a direction different from the transport direction.

4. The apparatus of claim 3, wherein a substrate motion is substantially horizontal.

5. The apparatus of claim 3, further including one or more actuators configured to move the masking arrangement continuously or stepwise.

6. The apparatus of claim 5, wherein the one or more actuators are configured to move the masking arrangement at least one of (i) while the substrate passes the masking arrangement, (ii) before the substrate passes the masking arrangement, and (iii) after the substrate has passed the masking arrangement.

7. The apparatus of claim 1, wherein the masking arrangement includes a first masking device configured for masking the first edge portion of the substrate and a second masking device configured for masking the second edge portion of the substrate.

8. The apparatus of claim 7, wherein the first masking device is configured to be movable in a first direction perpendicular to the transport direction, and wherein the second masking device is configured to be movable in a second direction opposite the first direction.

9. The apparatus of claim 8, wherein the first direction and the second direction are vertical directions.

10. The apparatus of claim 1, wherein the masking arrangement is stationary with respect to the transport direction while the substrate passes the masking arrangement and the one or more deposition sources.

11. The apparatus of claim 1, further including one or more detecting devices configured for detecting a deposition material accumulation on at least a portion of the masking arrangement.

12. The apparatus of claim 1, wherein the masking arrangement is configured to compensate for deposition material accumulation on the masking arrangement.

13. The apparatus of claim 1, wherein the apparatus is configured for dynamic sputter deposition on the substrate.

14. A method for masking a substrate during vacuum deposition, comprising:
masking at least one of a first edge portion and a second edge portion of the substrate using a masking arrangement while the substrate passes the masking arrangement and one or more deposition sources of an apparatus, wherein the first edge portion and the second edge portion are opposite edge portions of the substrate, and wherein the masking arrangement is stationary with respect to a transport direction of the substrate.

15. The method of claim 14, further including:
moving the masking arrangement in a direction perpendicular to the transport direction to compensate for deposition material accumulation on the masking arrangement.

16. A masking arrangement for use in an apparatus for vacuum deposition on a substrate, wherein the masking arrangement is configured to be mounted in a vacuum chamber of the apparatus stationary with respect to a transport direction of the substrate, and wherein the masking arrangement is configured for masking at least one of a first edge portion and a second edge portion of the substrate while the substrate passes the masking arrangement during a vacuum deposition process, wherein the first edge portion and the second edge portion are opposite edge portions of the substrate, the masking arrangement comprising:
a first masking device configured for masking the first edge portion of the substrate; and
a second masking device configured for masking the second edge portion of the substrate, wherein the first masking device is configured to be movable in a first direction different than the transport direction, and wherein the second masking device is configured to be movable in a second direction different than the transport direction.

17. The apparatus of claim 2, wherein the substrate is held substantially flat and a plane of the substrate is oriented vertically.

18. The apparatus of claim 3, wherein the masking arrangement is configured to be movable in a vertical direction.

19. The apparatus of claim 1, wherein the one or more deposition sources are sputter deposition sources.

20. The apparatus of claim 18, further including one or more actuators configured to move the masking arrangement continuously or stepwise.
